(19) United States
(12) Patent Application Publication
(10) Pub. No.: US 2026/0337810 A1
(43) Pub. Date: Oct. 29, 2026

(54) ELECTRODE, AND USE AND PREPARATION METHOD THEREOF

(71) Applicant: Magneto Special Anodes (Suzhou) Co., Ltd., Suzhou (CN)

(72) Inventors: Junwei XUE, Suzhou (CN); Hongyuan CHEN, Suzhou (CN)

(21) Appl. No.: 19/116,100

(22) PCT Filed: Oct. 2, 2022
(86) PCT No.: PCT/CN2022/123676

§ 371 Date: Mar. 27, 2025

(51) Int. Cl. C25D 17/14; C23C 14/35; C25D 3/38; H05K 3/18

(52) U.S. Cl. CPC C25D 17/14; C23C 14/35; C25D 3/38; H05K 3/188; H05K 2203/0723

(57) ABSTRACT

An electrode includes a substrate, an interlayer, and a catalytic layer. The interlayer is selected from a metal Ta layer, a Ti—Ta alloy layer, or a Ti—Pd alloy layer. The catalytic layer is selected from a precious metal oxide layer. The electrode can be used as an anode for reverse pulse electroplating.

### TECHNICAL FIELD

The present application relates to, but is not limited to, the field of electrochemistry, and specifically relates to, but is not limited to, an electrode, and use and a preparation method thereof.

### BACKGROUND OF THE RELATED ART

A printed circuit board is a main component of an electronic device, and is widely used as a connection carrier for integrated electronics and other devices. Electroplating, e.g., reverse pulse electroplating (RPP) of copper, is a common method for the preparation of a printed circuit board.

The reverse pulse electroplating of copper, which relies on redox reactions of iron ions, has very wide applications in printed circuit board electroplating. In the applications, an electroplating solution contains a large amount of divalent/trivalent iron ions in addition to copper sulfate and sulfuric acid that should be present for conventional copper plating, and no oxygen evolution reaction occurs on the surface of an anode, but only redox reactions of iron ions occur. In an environment lacking anodic polarization, no stable oxide layer can be formed on the surface of titanium which serves as a valve-type metal. Especially in a flash plating mode of such kind of pulse electroplating, the concentration of sulfuric acid in the plating solution is up to from 200 g/L to 250 g/L, which is highly corrosive to an interface between a titanium electrode coating and a matrix, resulting in frequent occurrence of abnormal coating peeling during use.

### SUMMARY

The following is a summary of the subject matter described in detail herein. This summary is not intended to limit the protection scope of the claims.

After years of careful research, the inventors of this application found that the key cause of the abnormal coating peeling lies in the corrosion of the interface. In order to enhance the lifetime of an electrode in reverse pulse electroplating applications, the corrosion resistance of the electrode is improved.

The present application provides an electrode which includes a substrate, an interlayer and a catalytic layer, wherein the interlayer may be selected from a metal Ta layer, a Ti—Ta alloy layer or a Ti—Pd alloy layer, and the catalytic layer may be selected from a precious metal oxide layer.

In some embodiments, the content of Ta in the interlayer Ti—Ta alloy layer may be no less than 10 wt %, further no less than 20 wt %, and still further from 40 wt % to 50 wt %, of the total mass of the alloy.

In some embodiments, the content of Pd in the interlayer Ti—Pd alloy layer may be from 0.01 wt % to 0.25 wt %, and further from 0.12 wt % to 0.25 wt %, of the total mass of the alloy.

In some embodiments, a loading amount of Ta in the interlayer Ta layer or the interlayer Ti—Ta alloy layer may be from 1 g/m² to 10 g/m², and further, may be 4 g/m² or 5 g/m².

In some embodiments, a loading amount of Ti in the interlayer Ti—Pd alloy layer may be from 1 g/m² to 10 g/m², and further, may be 4 g/m² or 5 g/m².

In some embodiments, the substrate may be selected from metal Ti or a Ti-based alloy.

In some embodiments, the catalytic layer may be selected from a Ru—Ti mixed metal oxide, an Ir—Ti mixed metal oxide, a Ru—Ir—Ti mixed metal oxide, a Ru—Ta mixed metal oxide, an Ir—Ta mixed metal oxide, or a Ru—Ir—Ta mixed metal oxide.

In some embodiments, the content of Ti or Ta in the catalytic layer may be from 10 wt % to 60 wt % of the total mass of metal elements.

In some embodiments, a loading amount of Ru or Ir in the catalytic layer may be from 2 g/m² to 20 g/m², further may be from 5 g/m² to 10 g/m², and still further may be 6 g/m² or 8 g/m².

The present application further provides use of the electrode described above, and the electrode may be used as an anode for electroplating, further for pulse electroplating, and still further for reverse pulse electroplating.

In some embodiments, the reverse pulse electroplating may be reverse pulse electroplating of copper, with iron ions as redox couples for anode reactions.

In some embodiments, the reverse pulse electroplating may be used for preparing a printed circuit board.

The present application further provides a method for preparing the electrode described above, including: providing an electrode substrate; forming an interlayer on the substrate by a vapor deposition method, e.g. a magnetron sputtering method; and forming a catalytic layer on the interlayer by a coating-heat treatment method.

Other features and advantages of the present application will be set forth in the following description, or may be learned by practice of the present application. Other advantages of the present application may be realized and obtained by the solutions described in the description and the drawings. Other aspects will be appreciated upon reading and understanding the accompanying drawings and detailed description.

### BRIEF DESCRIPTION OF THE DRAWINGS

The accompanying drawings are used to provide an understanding of the technical solutions of the present application, and constitute a part of the specification. They are used to explain the technical solutions of the present application together with the examples of the present application, and do not constitute a limitation to the technical solutions of the present application.

FIG. 1 is a sectional view of an electrode prepared in Example 1 under a scanning electron microscope (SEM).

FIG. 2 is a view of the surface of the electrode prepared in Example 1 under a scanning electron microscope (SEM).

In the drawings: 1. substrate; 2. interlayer; and 3. catalytic layer.

### DETAILED DESCRIPTION OF EMBODIMENTS

Examples of the present application will be described in detail below in conjunction with the drawings. It should be noted that the examples in the present application and the features in the examples may be arbitrarily combined with each other provided that there is no conflict.

An example of the present application provides an electrode. For example, the electrode includes a substrate, an interlayer and a catalytic layer which are sequentially stacked from bottom to top. The interlayer and the catalytic layer may also be arranged symmetrically on both sides of the substrate.

The substrate may be metal titanium (Ti), or a Ti-based alloy, e.g., a Ti—Nb alloy containing a small amount of Nb, a Ti—Ta alloy containing a small amount of Ta, or a Ti—Nb—Ta alloy containing a small amount of Nb and Ta, for example, the total content of Nb and Ta does not exceed 5 wt % of the total mass of the alloy. The substrate may be a metal titanium mesh.

The interlayer may be metal Ta or Ti alloy, for example, a Ti—Ta alloy or a Ti—Pd alloy, further for example, ASTM Grade 7 or ASTM Grade 11 Ti alloy, etc. The content of Ta in the Ti—Ta alloy may be not less than 10 wt %, further not less than 20 wt %, and still further from 40 wt % to 50 wt %, of the total mass of the alloy, for example, the mass ratio of Ta to Ti may be 40:60, 50:50, etc., The content of Pd in the Ti—Pd alloy may be from 0.01 wt % to 0.25 wt %, further from 0.12 wt % to 0.25 wt %, for example, 0.15 wt %, 0.18 wt %, 0.20 wt %, etc., of the total mass of the alloy The alloy content may provide both better oxidation resistance and better corrosion resistance.

The interlayer may be prepared by a vapor deposition method, e.g., a magnetron sputtering method, a chemical vapor deposition method, etc. A loading amount of Ta in the interlayer metal Ta layer or the interlayer Ti—Ta alloy layer may be from 1 g/m² to 10 g/m², for example, 4 g/m², 5 g/m², etc. A loading amount of Ti in the interlayer Ti—Pd alloy layer may be from 1 g/m² to 10 g/m², for example, 4 g/m² or 5 g/m², or a loading amount of Pd in the interlayer Ti—Pd alloy layer may be from 0.1 mg/m² to 25 mg/m², for example, 1 mg/m², 5 mg/m², 10 mg/m², 15 mg/m², etc. The magnetron sputtering method can especially enable the formation of a dense interlayer on the substrate, which further improves the corrosion resistance.

In an example of the magnetron sputtering process, the temperature of the substrate is controlled to from 200 °C to 400 °C, an inert gas is used as a sputtering gas, a vacuum degree is from 0.1 Pa to 0.5 Pa, the power of a DC power supply is from 100 W to 500 W, a target-substrate distance is from 30 mm to 100 mm, and a required loading amount is obtained by controlling the ratio of simultaneously used target materials and adjusting the sputtering time.

The material of the catalytic layer may be a Ru—Ti mixed metal oxide, an Ir—Ti mixed metal oxide, a Ru—Ir—Ti mixed metal oxide, a Ru—Ta mixed oxide, an Ir—Ta mixed oxide or a Ru—Ir—Ta mixed oxide, and the content of Ti or Ta element in the catalytic layer may be from 10 wt % to 60 wt % of the total mass of metal elements, for example, 20 wt %, 30 wt %, 40 wt %, 50 wt %, etc. The loading amount of Ru or Ir in the catalytic layer may be from 2 g/m² to 20 g/m², and further from 5 g/m² to 10 g/m², for example, 6 g/m², 8 g/m², etc.

The catalytic layer may be prepared by a coating-heat treatment method. The catalytic layer is formed by coating a coating solution, e.g., containing Ru and Ti, containing Ir and Ti, containing Ru, Ir and Ti, containing Ru and Ta, containing Ir and Ta, or containing Ru, Ir and Ta on the surface of the interlayer, drying and heat treatment. The coating-heat treatment process may be performed several times until a desired loading amount is obtained.

The electrode of the present application is suitable for use as an anode for reverse pulse electroplating, especially for reverse pulse electroplating of copper, for preparing a printed circuit board. By arranging an interlayer as described above, a stable, dense and highly corrosion-resistant oxide layer can be formed on the substrate, thereby reducing the corrosion to the interface between the substrate and the coating (especially a precious metal oxide coating), and achieving a good balance between oxidation resistance and corrosion resistance.

The present application has the following beneficial effects:

For the electrode of the present application, prior to coating of the catalytic layer, a corrosion-resistant valve-type metal interlayer (e.g., a metal Ta layer, a Ti—Ta alloy layer or a Ti—Pd alloy layer) is generated first on the substrate by a vapor deposition process. Due to the presence of this alloy interlayer, the corrosion resistance of the electrode in a high-concentration sulfuric acid solution is improved, and the lifetime of a titanium coated anode in the reverse pulse electroplating application is greatly prolonged.

### Example 1

Metal titanium (Ti) was used as an electrode substrate. A titanium plate meeting the requirement of ASTM-B265 Grade 1 was selected and stamped to obtain a 2 mm thick titanium mesh with a grid factor of 2.0, which was then sandblasted with iron sand and pickled with sulfuric acid.

An interlayer of a Ta—Ti alloy was formed on the Ti substrate by a magnetron sputtering method. The mass ratio of Ta to Ti in the alloy was 40:60, and the loading amount of Ta in the alloy layer was 4 g/m². Specifically, the titanium substrate was placed in a single-chamber magnetron sputtering system, the temperature of the titanium substrate was controlled to 300 °C, and magnetron sputtering was performed; wherein the sputtering gas was commercially available high-purity argon, the vacuum degree was 0.3 Pa, the power of the DC power supply was 200 W, the target-substrate distance was 50 mm, the titanium target and tantalum target were used together through controlling the ratio of target materials, and the sputtering lasted for 10 minutes.

A catalytic layer of an Ir—Ta mixed metal oxide was formed on the interlayer, wherein the loading amount of Ir was 8 g/m². A chloroiridium acid aqueous solution and a tantalum pentachloride salt were used to formulate an n-butanol solution with an iridium mass concentration of 3 wt %, in which the mass ratio of iridium element to tantalum element was 2:1. The solution was applied to the surface of the anode with a brush. Each time when 1 g iridium was applied per square meter of coating, the anode was dried at 80 °C and heat treated at 500 °C for 10 minutes, and then it was taken out for cooling and continued to be coated until the iridium loading target of 8 g/m² was reached.

An electrode was thus prepared.

### Example 2

The same metal titanium (Ti) as in Example 1 was used as an electrode substrate.

An interlayer of a Ta—Ti alloy was formed on the Ti substrate by a magnetron sputtering method. The mass ratio of Ta to Ti in the alloy was 50:50, and the loading amount of Ta in the alloy layer was 5 g/m². The formation steps of the interlayer were the same as those in Example 1 except for the alloy ratio and the loading amount.

A catalytic layer of an Ir—Ta mixed metal oxide was formed on the interlayer, in which the loading amount of Ir was 6 g/m². The formation steps of the catalytic layer were the same as those in Example 1 except for the loading amount.

An electrode was thus prepared.

### Example 3

The same metal titanium (Ti) as in Example 1 was used as an electrode substrate.

An interlayer of a Ta—Ti alloy was formed on the Ti substrate by a chemical vapor deposition method. The mass ratio of Ta to Ti in the alloy was 50:50, and the loading amount of Ta in the alloy layer was 5 g/m². Specifically, titanium dichloride was selected as a titanium source, tantalum dichloride was selected as a tantalum source, hydrochloric acid was used as a solvent; they were introduced into a reaction chamber at 500 °C and deposited for 20 minutes to reach a predetermined deposition amount.

A catalytic layer of an Ir—Ta mixed metal oxide was formed on the interlayer, in which the loading amount of Ir was 8 g/m². The formation steps of the catalytic layer were the same as those in Example 1 except for the loading amount.

An electrode was thus prepared.

### Comparative Example 1

The same metal titanium (Ti) as in Example 1 was used as an electrode substrate.

A catalytic layer of an Ir—Ta mixed metal oxide was formed on the Ti substrate, in which the loading amount of Ir was 12 g/m². The formation steps of the catalytic layer were the same as those in Example 1 except for the loading amount.

An electrode was thus prepared.

### Comparative Example 2

The same metal titanium (Ti) as in Example 1 was used as an electrode substrate.

A ceramic oxide interlayer was formed on the Ti substrate. An n-butanol solution of titanium trichloride and tantalum pentachloride, in which the metal element mass percentages of titanium and tantalum were both 2%, was coated on a titanium mesh, with a standard of 1 g metal element/m² in each layer. Then the titanium mesh was dried at 80 °C and heat treated at 500 °C for 1 hour, and then it was taken out for cooling and continued to be coated, to finally reach 3 g metal element/m².

A catalytic layer of an Ir—Ta mixed metal oxide was formed on the interlayer, in which the loading amount of Ir was 12 g/m². The formation steps of the catalytic layer were the same as those in Example 1 except for the loading amount.

An electrode was thus prepared.

### Electrode Microstructure

The electrode prepared in Example 1 was tested by a scanning electron microscope.

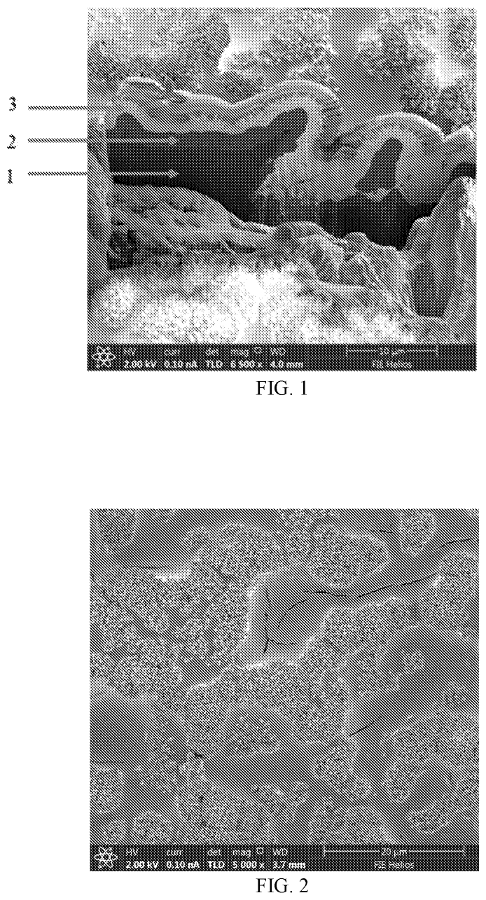

A sectional view of the electrode was shown in FIG. 1. As can be seen from FIG. 1, the interlayer can cover the surface of titanium matrix without cracks, which can avoid corrosion of the titanium matrix to the greater extent in subsequent applications.

The surface diagram of the electrode was shown in FIG. 2. As can be seen from FIG. 2, the interlayer has no impact on the surface of the iridium-tantalum catalytic layer, and the surface of the catalytic layer still exhibits normal patterns formed by precipitated iridium elements.

### Electrode Lifetime Test

A pulse power supply was used, the electrodes of the examples and comparative examples were respectively used as anodes, the cut anodes were connected with titanium plate cathodes of the same size by polypropylene bolts, with an electrode spacing of 3 cm, the test electrode (anode) was connected to the positive electrode, and the titanium cathode was connected to the negative electrode. The electrolyte was a mixed solution of copper sulfate (Cu 35 g/L) and sulfuric acid (H₂SO₄ 230 g/L), in which ferrous sulfate (with a ferrousion concentration of 17 g/L) was added. A forward current at an intensity of 800 A/m² was applied for 19 milliseconds, then a reverse current at an intensity of 2400 A/m² was applied for 1 millisecond, and these steps were cycled for pulse plating, with the temperature of the plating solution maintained at 40 °C.

The lifetime of the electrodes of the examples and the comparative examples was tested by an adhesive performance test. Specifically, 3M tape was adhered to the surfaces of the anodes which had experienced cyclic pulse electroplating, and then the tape was pulled down to observe whether the coating can be torn off to expose the titanium matrix. If the titanium matrix can be exposed obviously, it indicates that the interface between the coating and the titanium matrix has been separated and the coating has failed.

The test results were shown in Table 1.

TABLE 1
Lifetime of electrodes

| | | Ir—Ta catalytic | | |
|---|---|---|---|---|
| | Interlayer/Preparation | layer loading | | Lifetime |
| | method | amount (g/m² Ir) | | (kAh/m²) |
| Example 1 | 4 g/m² Ta for Ta/Ti (4:6) | 8 | g/m² | 2361 |
| | alloy/magnetron | | | |
| | sputtering | | | |
| Example 2 | 5 g/m² Ta for Ta/Ti (5:5) | 6 | g/m² | 2970 |
| | alloy/magnetron | | | |
| | sputtering | | | |
| Example 3 | 5 g/m² Ta for Ta/Ti (5:5) | 8 | g/m² | 1928 |
| | alloy/chemical vapor | | | |
| | deposition | | | |
| Comparative | None | 12 | g/m² | 927 |
| example 1 | | | | |
| Comparative | Ceramic oxide/heat | 12 | g/m² | 763 |

| | |
|---|---|
| example 2 | treatment at 500 °C for 1 h |

As can be seen from Table 1, the lifetimes of the electrodes (having a Ta—Ti alloy interlayer) in Examples 1-3 of the present application are longer than that of the electrode (excluding the interlayer) in Comparative example 1, and in particular the lifetime of the electrode in Example 2 is up to 2970 kAh/m², which is about 3.2 times that of the electrode in Comparative example 1. The main reason is that after the Ta—Ti alloy interlayer is applied, the surface of the alloy is oxidized and a dense and highly corrosion-resistant Ti—Ta oxide layer is formed on the interface between the Ti substrate and the Ir—Ta catalytic layer, and the wear rate of Ir in the catalytic layer is extremely low, thus improving the corrosion resistance of the electrode and prolonging its lifetime.

In addition, as can be seen from Table 1, the lifetimes of the electrodes (having a Ta—Ti alloy interlayer) in Examples 1-3 of the present application are longer than that of the electrode (having a ceramic oxide interlayer) in Comparative example 2, and in particular, the lifetime of the electrode in Example 2 is about 3.9 times that of the electrode in Comparative example 2. The main reason is that ceramic oxides are loose and porous, and cannot effectively protect the titanium substrate from corrosion; while in the electrodes in the examples of the present application, a dense and highly corrosion-resistant Ti—Ta oxide layer is formed on the interface between the Ti substrate and the Ir—Ta catalytic layer.

For Examples 1-3, the electrodes (Examples 1 and 2) with the interlayer prepared by a magnetron sputtering method have longer lifetimes than the electrode (Example 3) with the interlayer prepared by a chemical vapor deposition method, mainly because the metal layer formed by physical vapor deposition is denser, which is helpful for protecting the substrate from corrosion.

In Examples 1-2 in which the interlayers are both prepared by a magnetron sputtering method, the loading amount in Example 2 is higher than that in Example 1, and the lifetime in Example 2 is longer than that in Example 1, mainly because the loading amount of Ta is higher in Example 2, thereby improving the corrosion resistance. However, if the content of Ta is too high, the adhesion of the coating will decrease; and if the content of Ta is too low, the corrosion resistance will decrease. Therefore, the content of Ta in the interlayer is 40 wt %-50 wt % of the total mass of the alloy, which has achieved beneficial results.

Although the embodiments disclosed in the present application are as above, the contents described are only the embodiments adopted for the convenience of understanding the present application, and are not used to limit the present application. Any person skilled in the field to which the present application belongs can make any modifications and changes in the implementation form and details without departing from the spirit and scope disclosed by the present application, but the scope of patent protection of the present application shall still be subject to the scope defined by the appended claims.

1. An electrode, comprising:
a substrate;
an interlayer; and
a catalytic layer;
wherein the interlayer is selected from the group consisting of a metal Ta layer, a Ti—Ta alloy layer, and a Ti—Pd alloy layer; and
wherein the catalytic layer comprises a precious metal oxide layer.

2. The electrode according to claim 1, wherein the interlayer is a Ti—Ta alloy layer, and wherein the content of Ta in the interlayer Ti—Ta alloy layer is no less than 10 wt % of a total mass of the alloy.

3. The electrode according to claim 1, wherein the interlayer is a metal Ta layer or a Ti—Ta alloy layer, and wherein a loading amount of Ta in the interlayer is from 1 g/m² to 10 g/m².

4. The electrode according to claim 1, wherein the substrate is a metal Ti or a Ti-based alloy.

5. The electrode according to claim 1, wherein the catalytic layer is selected from the group consisting of a Ru—Ti mixed metal oxide, an Ir—Ti mixed metal oxide, a Ru—Ir—Ti mixed metal oxide, a Ru—Ta mixed metal oxide, an Ir—Ta mixed metal oxide, and a Ru—Ir—Ta mixed metal oxide.

6. The electrode according to claim 5, wherein a content of Ti or Ta in the catalytic layer is from 10 wt % to 60 wt % of a total mass of metal elements.

7. The electrode according to claim 1, wherein the precious metal is Ru or Ir, and wherein a loading amount of Ru or Ir in the catalytic layer is from 2 g/m² to 20 g/m².

8. An anode for electroplating, wherein the anode comprises the electrode of claim 1.

9. The anode of claim 8, wherein the anode is configured to conduct reverse pulse electroplating of copper, with iron ions as redox couples for anode reactions.

10. The anode of claim 9, wherein the reverse pulse electroplating is used for preparing a printed circuit board.

11. A method for preparing the electrode according to claim 1, the method comprising:
forming an interlayer on an electrode substrate by a vapor deposition method; and
forming a catalytic layer on the interlayer by a coating-heat treatment method.

12. The method of claim 11, wherein the vapor deposition method comprises magnetron sputtering.

13. The electrode of claim 1, wherein the interlayer is a Ti—Pd alloy layer, and the content of Pd in the interlayer Ti—Pd alloy layer is from 0.01 wt % to 0.25 wt % of a total mass of the alloy.

14. The electrode of claim 1, wherein the interlayer is a Ti—Pd alloy layer, and a loading amount of Ti in the interlayer Ti—Pd alloy layer is from 1 g/m² to 10 g/m².
